(19) United States
(12) Patent Application Publication
(10) Pub. No.: US 2025/0374546 A1
(43) Pub. Date: Dec. 4, 2025

(54) SEMICONDUCTOR DEVICE AND METHOD FOR MANUFACTURING THE SAME

(71) Applicant: Samsung Electronics Co., Ltd., Suwon-si (KR)

(72) Inventor: Kwang Yong Lee, Suwon-si (KR)

(21) Appl. No.: 18/983,818

(22) Filed: Dec. 17, 2024

(30) Foreign Application Priority Data
May 29, 2024 (KR) 10-2024-0070071

(51) Int. Cl. H10B 43/35; H10B 41/10; H10B 41/27; H10B 41/35; H10B 41/41; H10B 43/10; H10B 43/27; H10B 43/40; H10D 84/83

(52) U.S. Cl. CPC H10B 43/35; H10B 41/27; H10B 41/35; H10B 41/41; H10B 43/27; H10B 43/40; H10D 84/83; H10B 41/10; H10B 43/10

(57) ABSTRACT

A semiconductor device includes a first substrate including an element region and an edge region, peripheral insulating films on the first substrate, a memory cell structure on the peripheral insulating films in the element region, a planarization insulating film at least partially covering an end portion of the memory cell structure and the peripheral insulating films, cell insulating films on the memory cell structure and the planarization insulating film, a penetration via penetrating at least a portion of the peripheral insulating films and the planarization insulating film in the element region, a cell via on the penetration via, a dummy pattern penetrating at least a portion of the peripheral insulating films and the planarization insulating film in the edge region, and a guide pattern penetrating the cell insulating films to contact the dummy pattern.

### CROSS-REFERENCE TO RELATED APPLICATION

This U.S. non-provisional patent application claims priority under 35 U.S.C. § 119 of Korean Patent Application No. 10-2024-0070071, filed on May 29, 2024, the entire contents of which are hereby incorporated by reference.

### BACKGROUND

The present disclosure herein relates to a semiconductor device and a method for manufacturing the same.

In general, a wafer on which semiconductor devices are formed is divided into a chip region on which a plurality of cells is formed and a scribe lane for separating chips. A plurality of semiconductor devices, for example, a transistor, a resistor, a capacitor, etc., are formed on the chip region, but the semiconductor device is not formed on the scribe lane, and the semiconductor device is completed as a chip by sawing the wafer along the scribe lane. Test patterns for confirming that processes are normally performed by monitoring electrical characteristics of the semiconductor device provided in the chip region, whether there is a defect pattern, and the like, an align key for a lithography process, or the like may be disposed on the scribe lane.

### SUMMARY

The present disclosure may provide a semiconductor device with improved reliability.

The present disclosure also may provide a method for manufacturing a semiconductor device capable of increasing a yield.

A technical goal of the inventive concept is not limited to the goal mentioned above, and other technical goals that are not mentioned may be clearly understood from description below by those skilled in the art.

An embodiment of the inventive concept provides a semiconductor device including a first substrate including an element region and an edge region, peripheral insulating films on the first substrate, a memory cell structure on the peripheral insulating films in the element region, a planarization insulating film at least partially covering the peripheral insulating films and an end portion of the memory cell structure, cell insulating films on the memory cell structure and the planarization insulating film, a penetration via penetrating at least a portion of the peripheral insulating films and the planarization insulating film in the element region, a cell via on the penetration via, a dummy pattern penetrating at least a portion of the peripheral insulating films and the planarization insulating film in the edge region, and a guide pattern penetrating the cell insulating films to contact the dummy pattern, wherein the guide pattern has a first height from an upper end of the dummy pattern, and wherein the cell via has a second height, from an upper end of the penetration via, smaller than the first height.

In an embodiment of the inventive concept, a semiconductor device includes a first substrate including an element region and an edge region, peripheral transistors on the first substrate, peripheral insulating films on the first substrate and the peripheral transistors, a stack structure on the peripheral insulating films in the element region, and including electrode layers and interelectrode insulating films alternately repeatedly stacked, vertical channel structures at least partially penetrating the stack structure, a planarization insulating film at least partially covering the peripheral insulating films and an end portion of the stack structure, cell insulating films on the stack structure and the planarization insulating film, a penetration via penetrating at least a portion of the peripheral insulating films and the planarization insulating film in the element region, a cell via on the penetration via, a dummy pattern penetrating at least a portion of the peripheral insulating films and the planarization insulating film in the edge region, and a guide pattern penetrating the cell insulating films to be in contact with the dummy pattern, wherein the guide pattern has a first sidewall that is free of the cell insulating films, wherein the dummy pattern has a second sidewall that is free of the peripheral insulating films and the planarization insulating film, and wherein the first sidewall and the second sidewall are arranged to have a step relationship with each other.

In an embodiment of the inventive concept, a semiconductor device includes a first substrate including an element region and an edge region, peripheral insulating films on the first substrate, a memory cell structure on the peripheral insulating films in the element region, a planarization insulating film at least partially covering the peripheral insulating films and an end portion of the memory cell structure, cell insulating films on the memory cell structure and the planarization insulating film, a dummy pattern penetrating at least a portion of the peripheral insulating films and the planarization insulating film in the edge region, and a guide pattern penetrating the cell insulating films to contact the dummy pattern, wherein the guide pattern has a first sidewall free of the cell insulating films, wherein the dummy pattern has a second sidewall free of the peripheral insulating films and the planarization insulating film, and wherein the first sidewall has lower surface roughness than the second sidewall.

In an embodiment of the inventive concept, a method for manufacturing a semiconductor device includes providing a first substrate including element regions and a scribe lane region therebetween, forming peripheral transistors and peripheral insulating films on the first substrate, forming a memory cell structure on the peripheral insulating films, forming a planarization insulating film at least partially covering the memory cell structure and the peripheral insulating films, forming dummy vias and penetration vias penetrating the planarization insulating film, forming cell insulating films at least partially covering the penetration vias and the dummy vias, forming guide patterns at least partially penetrating the cell insulating films to overlap an upper surface of the dummy vias with respect to the first substrate, and polishing a rear surface of the first substrate, wherein the dummy vias are configured to have a void thereinside.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view of a semiconductor device according to embodiments of the inventive concept;

FIG. 2 is a cross-sectional view taken along line A-A′ of FIG. 1 according to embodiments of the inventive concept;

FIG. 3A is an enlarged diagram of portion ‘P1’ of FIG. 2;

FIG. 3B is an enlarged diagram of portion ‘P2’ of FIG. 2;

FIG. 3C is an enlarged diagram of portion ‘P3’ of FIG. 2;

FIG. 4 is a diagram schematically illustrating an electronic system of a semiconductor device according to an embodiment of the inventive concept;

FIG. 5 is a plan view of a wafer;

FIGS. 6A, 6B, 6C, 6D, 6E, 6F, 6G, 6H, 6I, 6J, and 6K are cross-sectional views sequentially illustrating operations of manufacturing a semiconductor device having the cross-section of FIG. 2;

FIG. 7 is a plan view of a semiconductor device according to embodiments of the inventive concept;

FIG. 8 is a cross-sectional view taken along line A-A′ of FIG. 1 according to embodiments of the inventive concept;

FIG. 9 is a cross-sectional view taken along line A-A′ of FIG. 1 according to embodiments of the inventive concept;

FIG. 10 is a cross-sectional view taken along line A-A′ of FIG. 1 according to embodiments of the inventive concept;

FIG. 11 is a cross-sectional view taken along line A-A′ of FIG. 1 according to embodiments of the inventive concept;

FIG. 12 is a cross-sectional view taken along line A-A′ of FIG. 1 according to embodiments of the inventive concept; and

FIG. 13 is a cross-sectional view of a semiconductor package according to embodiments of the inventive concept.

### DETAILED DESCRIPTION

Hereinafter, embodiments of the inventive concept will be described with reference to the accompanying drawings in more detail in order to more specifically describe the inventive concept.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device. It is noted that aspects described with respect to one embodiment may be incorporated in different embodiments although not specifically described relative thereto. That is, all embodiments and/or features of any embodiments can be combined in any way and/or combination.

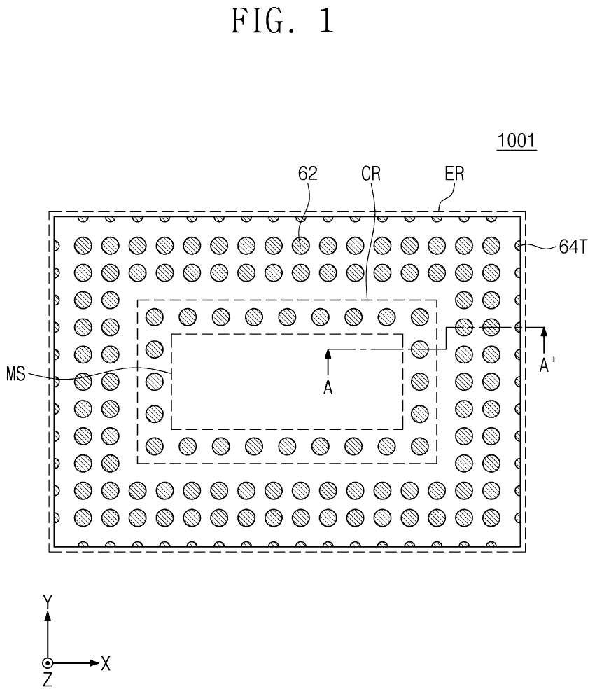

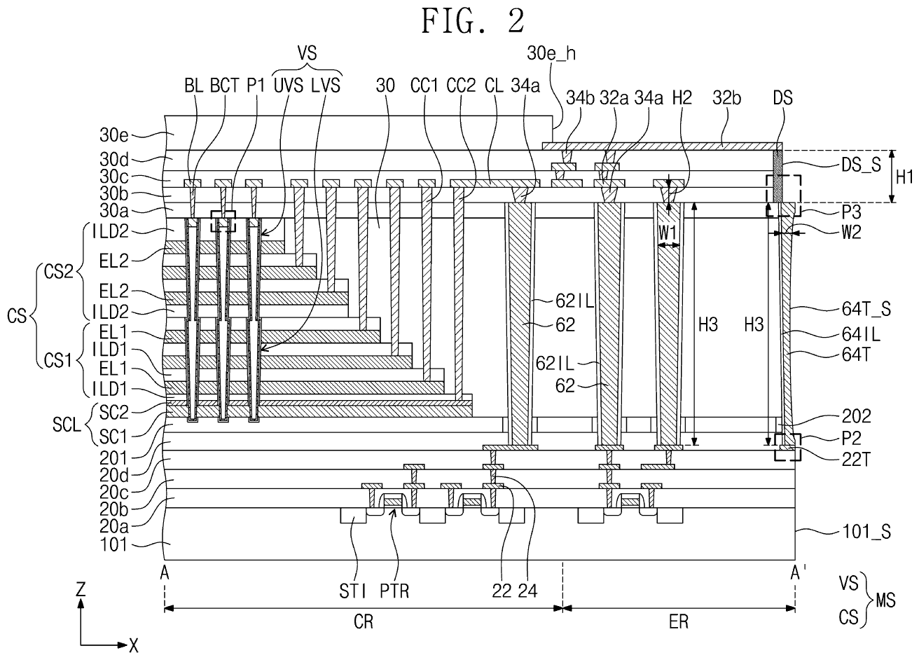

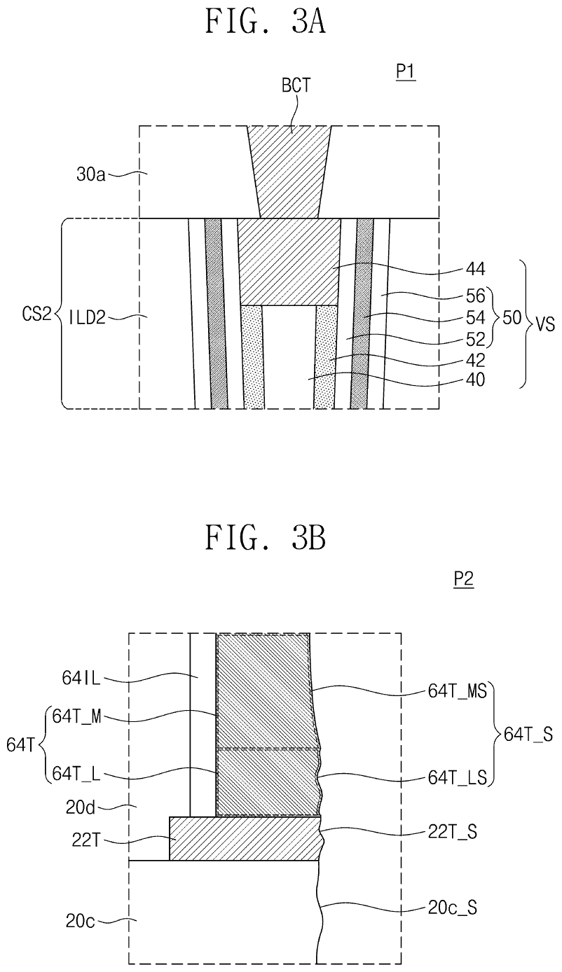

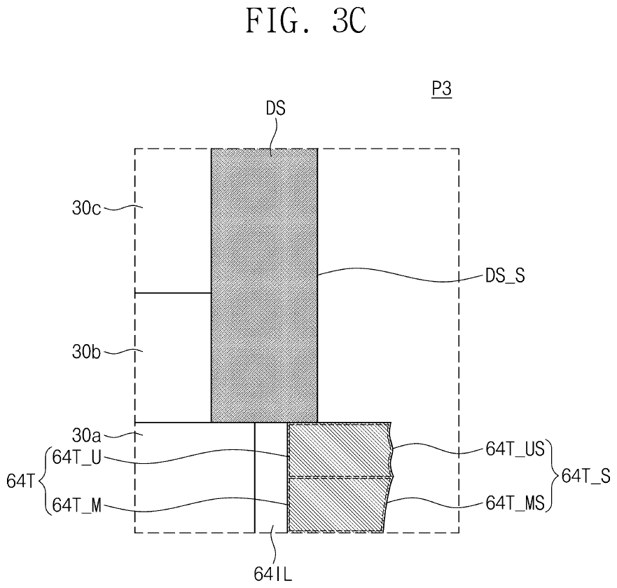

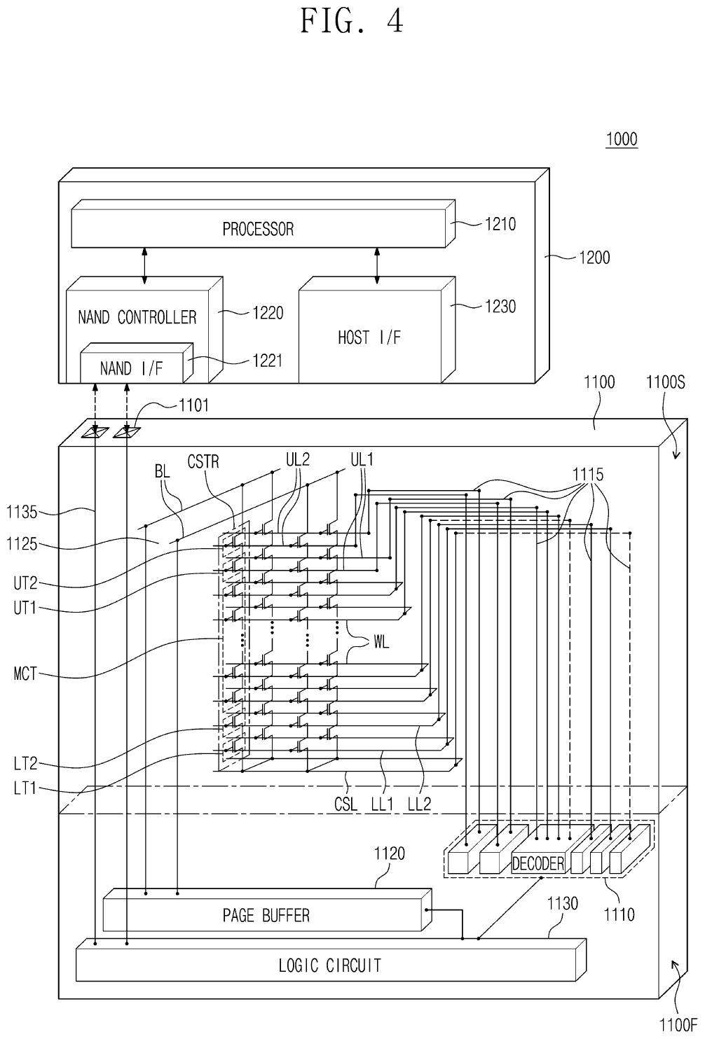

FIG. 1 is a plan view of a semiconductor device according to embodiments of the inventive concept. FIG. 2 is a cross-sectional view taken along line A-A′ of FIG. 1 according to embodiments of the inventive concept. FIG. 3A is an enlarged diagram of portion ‘P1’ of FIG. 2. FIG. 3B is an enlarged diagram of portion ‘P2’ of FIG. 2. FIG. 3C is an enlarged diagram of portion ‘P3’ of FIG. 2. FIG. 4 is a diagram schematically illustrating an electronic system of a semiconductor device according to an embodiment of the inventive concept.

Referring to FIGS. 1, 2, and 3A, a semiconductor device 1001 according to the present embodiment may include an edge region ER and an element region CR. The edge region ER may surround the element region CR. The semiconductor device 1001 may include a peripheral circuit structure PS and an upper structure MS disposed thereon. The upper structure MS may include a stack structure CS and vertical channel structures VS penetrating the same. As used herein, ‘the upper structure’ may be referred to as ‘a memory cell structure’. Further, as used herein, “penetrating” or variations thereof means to extend through. “Penetrating” or variations thereof may be modified with phrases, such as, for example, “at least partially” or “a portion of” to indicate that one element does not extend through an entirety of another element, but only a part or portion of another element.

The peripheral circuit structure PS may include a first substrate 101. For example, the first substrate 101 may include a semiconductor material. For example, the first substrate 101 may be a monocrystalline epitaxial layer grown on a silicon substrate, a silicon-germanium substrate, a germanium substrate, or a monocrystalline silicon substrate. Active regions may be defined by disposing an element isolation film STI on the first substrate 101. Peripheral transistors PTR may be disposed on the first substrate 101. The peripheral transistors PTR may correspond to a path transistor and/or a bit line selection transistor for driving the upper structure MS.

First to fourth peripheral insulating films 20a, 20b, 20c, and 20d may be sequentially disposed on the first substrate 101. The peripheral transistors PTR may be covered with a first peripheral insulating film 20a. Peripheral lines 22 may be respectively disposed on the first to third peripheral insulating films 20a, 20b, and 20c. Peripheral vias 24 may be respectively disposed in the first to third peripheral insulating films 20a, 20b, and 20c. Some of the peripheral vias 24 may be in contact with source/drain regions of the peripheral transistors PTR. Some of the peripheral vias 24 may be in contact with some of the peripheral lines 22. A fourth peripheral insulating film 20d may be disposed on the third peripheral insulating film 20c and may cover the peripheral lines 22 on the third peripheral insulating film 20c.

The first to fourth peripheral insulating films 20a, 20b, 20c, and 20d may each have a single-or multi-filmed structure of at least one of silicon oxide, silicon nitride, silicon oxynitride, silicon carbonitride, or a porous insulating material. For example, the peripheral lines 22 and the peripheral vias 24 may each include at least one of copper, aluminum, tungsten, nickel, gold, tin, or titanium.

A second substrate 201 may be disposed on the fourth peripheral insulating film 20d. For example, the second substrate 201 may include a semiconductor material. The second substrate 201 may be referred to as ‘a semiconductor layer’ or ‘a silicon layer’. For example, the second substrate 201 may be doped with first conductive type impurities. For example, the first conductive type impurities may be boron which has a P-type. Alternatively, the first conductive type impurities may be arsenic or phosphorous which have an N-type.

A source structure SCL may be disposed on the second substrate 201. The source structure SCL may be disposed on the element region CR. The source structure SCL may include a first source pattern SC1 and a second source pattern SC2 thereon. The first source pattern SC1 may include a semiconductor pattern doped with impurities, for example, polysilicon doped with the impurities. The second source pattern SC2 may include a semiconductor pattern doped with impurities, for example, polysilicon doped with the first conductive type impurities. The first source pattern SC1 may further include a semiconductor material different from the second source pattern SC2. A conductive type of the impurities doped in the first source pattern SC1 may be the same as that of the impurities doped in the second source pattern SC2. A concentration of the impurities doped in the first source pattern SC1 may be the same as or different from that of the impurities doped in the second source pattern SC2. The source structure SCL may function as a common source line in the upper structure MS.

The stack structure CS may be disposed on the source structure SCL. The stack structure CS may include a first stack structure CS1 and a second stack structure CS2 disposed thereon. The first stack structure CS1 may include first electrode layers EL1 and first interelectrode insulating films ILD1 alternately stacked. The second stack structure CS2 may include second electrode layers EL2 and second interelectrode insulating films ILD2 alternately stacked. End portions of the first and second electrode layers EL1 and EL2 and the first and second interelectrode insulating films ILD1 and ILD2 may have step forms.

More specifically, the second stack structure CS2 may be disposed on an upper surface of the uppermost first interelectrode insulating film ILD1 of the first stack structure CS1. The uppermost first interelectrode insulating film ILD1 of the first stack structure CS1 and the lowermost second interelectrode insulating film ILD2 of the second stack structure CS2 may be in contact with each other. However, the inventive concept is not limited thereto, and a single-layered insulating film may be provided between the uppermost first electrode layer EL1 of the first stack structure CS1 and the lowermost second electrode layer EL2 of the second stack structure CS2.

A lowermost first electrode layer EL1 and a first electrode layer EL1 located thereon among the first electrode layers EL1 may correspond to gate electrodes of a lower erase control transistor and a ground selection transistor. Two uppermost second electrode layers EL2 among the second electrode layers EL2 may be separated to a plurality of lines to correspond to gate electrodes of an upper erase control transistor and a string selection transistor. Other first and second electrode layers EL1 and EL2 may correspond to word lines. At least one of the other first and second electrode layers EL1 and EL2 may be a dummy word line that does not actually operate.

For example, the first and second electrode layers EL1 and EL2 may include at least one selected from doped semiconductor (ex, doped silicon, or the like), metal (ex, tungsten, copper, aluminum, or the like), a conductive metal nitride (ex, titanium nitride, tantalum nitride, or the like), transition metal (ex, titanium, tantalum), or the like. The first and second interelectrode insulating films ILD1 and ILD2 may include at least one single-or multi-film selected from a silicon oxide film, a silicon nitride film, a silicon oxynitride film, and a porous insulating film.

The vertical channel structures VS may penetrate the stack structure CS and the source structure SCL to be adjacent to the second substrate 201. Each of the vertical channel structures VS may include a first vertical extension LVS and a second vertical extension UVS thereon. The first vertical extension LVS may penetrate the first stack structure CS1 and the source structure SCL to be adjacent to the second substrate 201. The second vertical extension UVS may penetrate the second stack structure CS2.

The first vertical extension LVS and the second vertical extension UVS may each include a buried insulating pattern 40, a vertical semiconductor pattern 42, and a gate insulating film 50. The gate insulating film 50 may include a charge storage film 54 used as a data storage pattern.

For example, the vertical semiconductor patterns 42 may include silicon. The vertical semiconductor patterns 42 may each have a vacant cup form. The inside of each of the vertical semiconductor patterns 42 may be filled with the buried insulating pattern 40. For example, the buried insulating pattern 40 may have a single-or multi-filmed structure of at least one of a silicon oxide film, a silicon nitride film, or a silicon oxynitride film. A conductive pad 44 may be disposed on the buried insulating pattern 40 and the vertical semiconductor patterns 42. The conductive pad 44 may include polysilicon doped with impurities, or metal such tungsten, aluminum, and copper.

The gate insulating film 50 may be interposed between the vertical semiconductor pattern 42 and the stack structure CS. The gate insulating film 50 may include a tunnel insulating film 52, a charge storage film 54, and a blocking insulating film 56. The tunnel insulating film 52 may be one of materials having a greater band gap than the charge storage film 54. For example, the tunnel insulating film 52 may include silicon oxide. The blocking insulating film 56 may be a silicon oxide film, or a high dielectric film having a greater dielectric constant than silicon oxide. For example, the high dielectric film may include a metal oxide such as aluminum oxide and hafnium oxide. The charge storage film 54 may be an insulating film including a trap insulating film, a floating gate electrode, or conductive nano dots. More specifically, the charge storage film 54 may include at least one of a silicon nitride film, a silicon oxynitride film, a Si-rich nitride film, nanocrystalline Si and a laminated trap layer. The first source pattern SC1 may penetrate the gate insulating film 50 to be in contact with the vertical semiconductor patterns 42.

A planarization insulating film 30 may cover an end portion of the stack structure CS and the second substrate 201. For example, the planarization insulating film 30 may have a single-or multi-filmed structure of at least one of silicon oxide, silicon nitride, silicon oxynitride, or a porous insulating material. First to fifth cell insulating films 30a to 30e may be sequentially disposed on the planarization insulating film 30 and the stack structure CS. For example, the first to fifth cell insulating films 30a to 30e may have a single-or multi-filmed structure of at least one of silicon oxide, silicon nitride, silicon oxynitride, or a porous insulating material.

A first cell insulating film 30a may cover the stack structure CS and the planarization insulating film 30. Bit line contacts BCT may penetrate first and second cell insulating films 30a and 30b to be respectively in contact with the conductive pads 44. Bit lines BL may be disposed on a second cell insulating film 30b in the element region CR. The conductive pads 44 may be respectively connected to the bit lines BL by the bit line contact BCT.

First cell lines CL may be disposed on the second cell insulating film 30b in the element region CR. The first cell lines CL may be disposed spaced apart from the bit lines BL. Second cell lines 32a may be respectively disposed on the second cell insulating film 30b and the third cell insulating film 30c in the edge region ER. A third cell line 32b may be disposed on the fourth cell insulating film 30d in the edge region ER. One sidewall of the third cell line 32b may be exposed. A fifth cell insulating film 30e may be disposed on the fourth cell insulating film 30d. The fifth cell insulating film 30e may include a hole 30e_h exposing the third cell line 32b. First cell vias 34a may be disposed in the second cell insulating film 30b. Second cell vias 34b may be respectively disposed in the third and fourth cell insulating films 30c and 30d. For example, the first to third cell lines CL, 32a, and 32b and the first and second cell vias 34a and 34b may each include at least one of copper, aluminum, tungsten, nickel, gold, tin, or titanium.

First and second cell contact plugs CC1 and CC2 may be disposed in the planarization insulating film 30. First cell contact plugs CC1 may respectively penetrate the planarization insulating film 30, the first and second cell insulating films 30a and 30b, and the first and second interelectrode insulating films ILD1 and ILD2 to be in contact with the first and second electrode layers EL1 and EL2. The first cell contact plugs CC1 may connect end portions of the first and second electrode layers EL1 and EL2 to a portion of the first cell lines CL.

A second cell contact plug CC2 may penetrate the planarization insulating film 30, the first and second cell insulating films 30a and 30b, and the first interelectrode insulating film ILD1 to be in contact with an end portion of the first source pattern SC1. The second cell contact plug CC2 may connect the end portion of the first source pattern SC1 to another portion of the first cell lines CL.

Penetration vias 62 may penetrate the fourth peripheral insulating film 20d, the second substrate 201, the planarization insulating film 30, and the first cell insulating film 30a to be respectively in contact with the peripheral lines 22 in the element region CR and the edge region ER. The penetration vias 62 may be spaced apart from each other. Some of the penetration vias 62 may be disposed in the element region CR. The others of the penetration vias 62 may be disposed in the edge region ER. As in FIG. 1, the penetration vias 62 may be disposed to surround the upper structure MS on a plane. The penetration vias 62 may be spaced apart from each other in a first direction X and a second direction Y.

The first cell vias 34a may be respectively disposed on the penetration vias 62. The penetration vias 62 disposed in the element region CR may be respectively partially connected to the first cell lines CL by the first cell vias 34a disposed in the second cell insulating film 30b. The penetration vias 62 disposed in the edge region ER may be respectively partially connected to the second cell lines 32a by the first cell vias 34a disposed in the second cell insulating film 30b.

A substrate insulating film 202 may be interposed between the penetration via 62 and the second substrate 201. For example, the substrate insulating film 202 may have a single-or multi-filmed structure of at least one of silicon oxide, silicon nitride, or silicon oxynitride. A first via insulating film 62IL may be interposed between the penetration vias 62 and the fourth peripheral insulating film 20d, between the penetration vias 62 and the second substrate 201, between the penetration vias 62 and the substrate insulating film 202, between the penetration vias 62 and the planarization insulating film 30, and between the penetration vias 62 and the first cell insulating film 30a.

A dummy pattern 64T may penetrate the fourth peripheral insulating film 20d, the second substrate 201, the planarization insulating film 30, and the first cell insulating film 30a to be in contact with a line residual pattern 22T in the edge region ER. The dummy pattern 64T may be disposed on an edge of the planarization insulating film 30. The line residual pattern 22T may be disposed on an edge of the fourth peripheral insulating film 20d. The dummy pattern 64T may be spaced apart from the penetration vias 62 to be disposed in the outermost side of the edge region ER.

A sidewall 64T_S of the dummy pattern 64T may not be covered with the fourth peripheral insulating film 20d, the second substrate 201, the planarization insulating film 30, and the first cell insulating film 30a, and may be exposed. The sidewall 64T_S of the dummy pattern 64T may be aligned with a sidewall 101_S of the first substrate 101. The dummy pattern 64T may be provided in plurality. As in FIG. 1, the dummy patterns 64T may be disposed to surround the penetration vias 62 on a plane. The dummy patterns 64T may be spaced apart from each other in the first direction X and the second direction Y.

The substrate insulating film 202 may be interposed between the dummy pattern 64T and the second substrate 201. A second via insulating film 64IL may be interposed between the dummy pattern 64T and the fourth peripheral insulating film 20d, between the dummy pattern 64T and the second substrate 201, between the dummy pattern 64T and the substrate insulating film 202, between the dummy pattern 64T and the planarization insulating film 30, and between the dummy pattern 64T and the first cell insulating film 30a. For example, the penetration vias 62 and the dummy pattern 64T may include at least one metal selected from tungsten, aluminum, copper, titanium, and tantalum. The penetration vias 62 and the dummy pattern 64T may include the same material. For example, each of the first and second via insulating films 62IL and 64IL may include an insulating material such as a silicon oxide film, a silicon nitride film, or a silicon oxynitride film.

A guide pattern DS may penetrate second to fourth cell insulating films 30b, 30c, and 30d to be in contact with the dummy pattern 64T. The guide pattern DS may be in contact with the third cell line 32b. The guide pattern DS may overlap the dummy pattern 64T. One sidewall DS_S of the guide pattern DS may not be covered with the second to fourth cell insulating films 30b, 30c, and 30d and may be exposed. The one sidewall DS_S of the guide pattern DS may not be aligned with the sidewall 64T_S of the dummy pattern 64T and may have a step therewith. The one sidewall DS_S of the guide pattern DS may be aligned with a sidewall of the third cell line 32b. For example, the guide pattern DS may include metal such as tungsten, aluminum, titanium, or copper.

The guide pattern DS may be disposed in the outermost side of the edge region ER in a plan view and may surround the element region CR. The guide pattern DS may cover side surfaces of the second to fourth cell insulating films 30b, 30c, and 30d to prevent moisture or the like from infiltrating from the outside to the inside of the second to fourth cell insulating films 30b, 30c, and 30d. Accordingly, reliability of the semiconductor device 1001 may be improved.

The penetration vias 62 may have a first width W1 in the first direction X. The dummy pattern 64T may have a second width W2 smaller than the first width W1 in the first direction X. The guide pattern DS may have a first height H1 from an upper end of the dummy pattern 64T in a third direction Z. The first cell vias 34a may have a second height H2, from upper ends of the penetration vias 62 in the third direction Z, smaller than the first height H1. The penetration vias 62 and the dummy pattern 64T may have the same third height H3. However, an embodiment of the inventive concept is not limited thereto, and the penetration vias 62 and the dummy pattern 64T may have different heights.

Referring to FIGS. 2, 3B, and 3C, the dummy pattern 64T may include a first part 64T_M, a second part 64T_L located under the first part 64T_M, and a third part 64T_U located on the first part 64T_M. The first to third parts 64T_M, 64T_L, and 64T_U may respectively include first to third sidewalls 64T_MS, 64T_LS, and 64T_US not covered with the planarization insulating film 30 and the fourth peripheral insulating film 20d and exposed.

A second sidewall 64T_LS of the dummy pattern 64T, a sidewall 22T_S of the line residual pattern 22T, and a sidewall 20c_S of the third peripheral insulating film 20c may be aligned with each other. The second and third sidewalls 64T_LS and 64T_US may have greater surface roughness than the first sidewall 64T_MS. The sidewall DS_S of the guide pattern DS may have smaller surface roughness than the third sidewall 64T_US of the dummy pattern 64T. The sidewall 22T_S of the line residual pattern 22T may have greater surface roughness than the sidewall DS_S of the guide pattern DS.

Referring to FIG. 4, an electronic system 1000 according to an exemplary embodiment of the inventive concept may include a semiconductor device 1100 and a controller 1200 electrically connected to the semiconductor device 1100. The electronic system 1000 may be a storage device including one or a plurality of semiconductor devices 1100, or an electronic device including the storage device. For example, the electronic system 1000 may be a solid state drive (SSD) device, a universal serial bus (USB), a computing system, a medical device, or a communication device including the one or the plurality of semiconductor devices 1100.

The semiconductor device 1100 may be an involatile memory device, for example, a NAND flash memory device. The semiconductor device 1100 may include a first structure 1100F, and a second structure 1100S on the first structure 1100F. The semiconductor device 1100 may correspond to the semiconductor device 1001 of FIG. 2.

The first structure 1100F may be a peripheral circuit structure including a decoder circuit 1110, a page buffer 1120, and a logic circuit 1130. The peripheral transistors PTR, the peripheral lines 22, and the like of FIG. 2 may constitute the decoder circuit 1110, the page buffer 1120, and the logic circuit 1130.

The second structure 1100S may be a memory cell structure including the bit line BL, the common source line CSL, the word lines WL, the first and second gate upper lines UL1 and UL2, the first and second gate lower lines LL1 and LL2, and memory cell strings CSTR between the bit line BL and the common source line CSL. The first and second electrode layers EL1 and EL2 of the stack structure CS of FIG. 2 may constitute the common source line CSL, the word line WL, the first and second gate upper lines UL1 and UL2, and the first and second gate lower lines LL1 and LL2.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. A number of the lower transistors LT1 and LT2 and a number of the upper transistors UT1 and UT2 may be variously changed according to embodiments.

According to exemplary embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2. The word lines WL may be gate electrodes of the memory cell transistors MCT, and the upper lines UL1 and UL2 may be respectively gate electrodes of the upper transistors UT1 and UT2.

According to exemplary embodiments, the lower transistors LT1 and LT2 may include a lower erase control transistor LT1 and a ground selection transistor LT2 connected in series. The upper transistors UT1 and UT2 may include a string selection transistor UT1 and an upper erase control transistor UT2 connected in series. At least one of the lower erase control transistor LT1 and the upper erase control transistor UT2 may be used in an erase operation of deleting a data stored in the memory cell transistors MCT by using a gate induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115 extending to the second structure 1100S in the first structure 1100F. The bit lines BL may be electrically connected to the page buffer 1120 through second connection lines 1125 extending to the second structure 1100S in the first structure 1100F.

In the first structure 1100F, the decoder circuit 1110 and the page buffer 1120 may perform a control operation for at least one memory cell transistor among the plurality of memory cell transistors MCT. The decoder circuit 1110 and the page buffer 1120 may be controlled by the logic circuit 1130. The semiconductor device 1100 may communicate with the controller 1200 through an input-output pad 1101 electrically connected to the logic circuit 1130. The input-output pad 1101 may be electrically connected to the logic circuit 1130 through an input-output connection line 1135 extending to the second structure 1100S in the first structure 1100F.

The controller 1200 may include a processor 1210, a NAND controller 1220, and a host interface 1230. According to embodiments, the electronic system 1000 may include the plurality of semiconductor devices 1100, and in this case, the controller 1200 may control the plurality of semiconductor device 1100.

The processor 1210 may control overall operations of the electronic system 1000 including the controller 1200. The processor 1210 may operate according to a predetermined firmware and may access to the semiconductor device 1100 by controlling the NAND controller 1220. The NAND controller 1220 may include a NAND interface 1221 that processes communication with the semiconductor device 1100. A control command for controlling the semiconductor device 1100, a data to be recorded in the memory cell transistors MCT of the semiconductor device 1100, a data to be read from the memory cell transistors MCT of the semiconductor device 1100, and the like may be transmitted through the NAND interface 1221. The host interface 1230 may supply a communication function between the electronic system 1000 and an external host. After receiving a control command from the external host through the host interface 1230, the processor 1210 may control the semiconductor device 1100 in response to the control command.

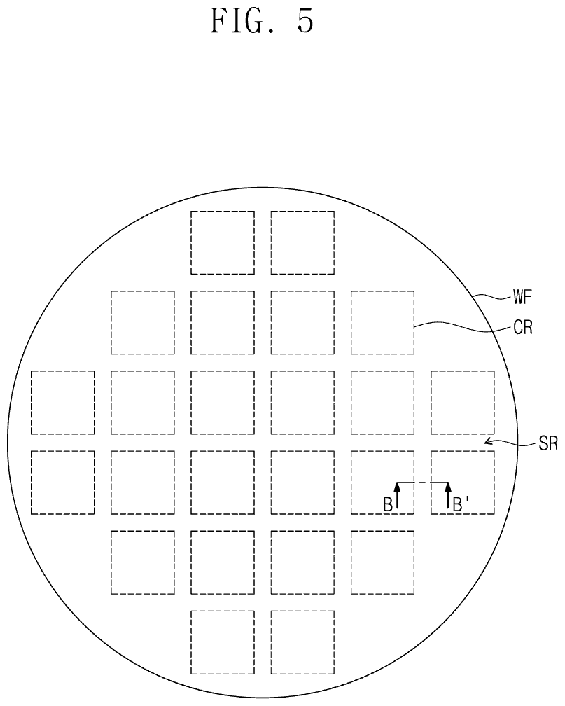

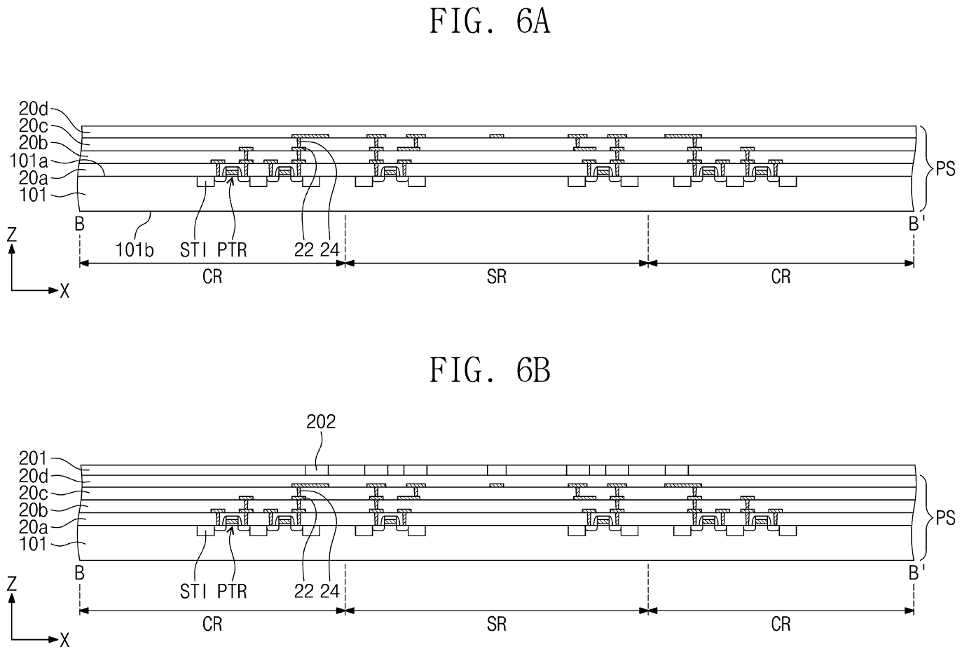

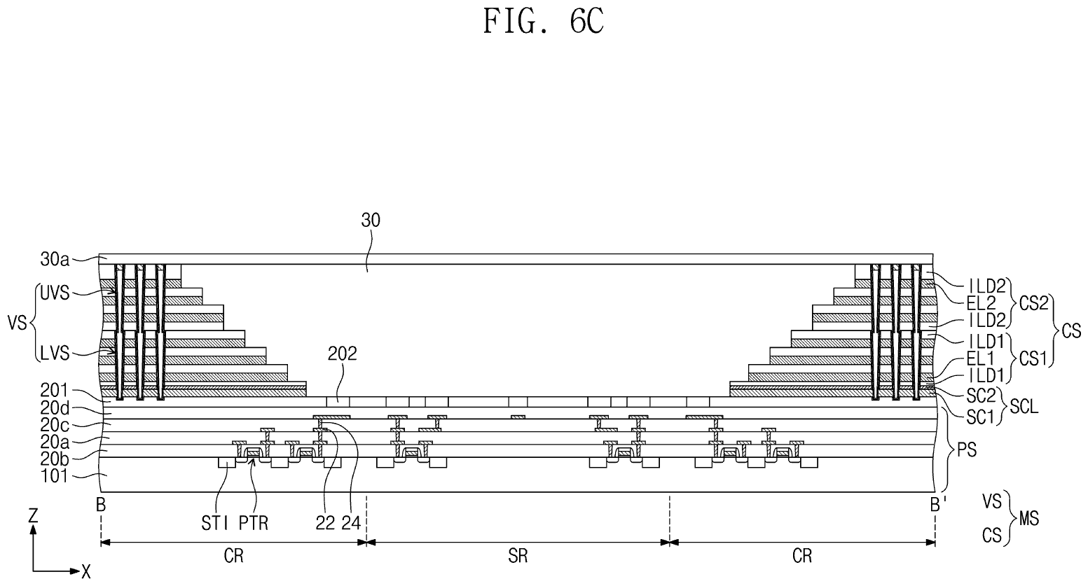

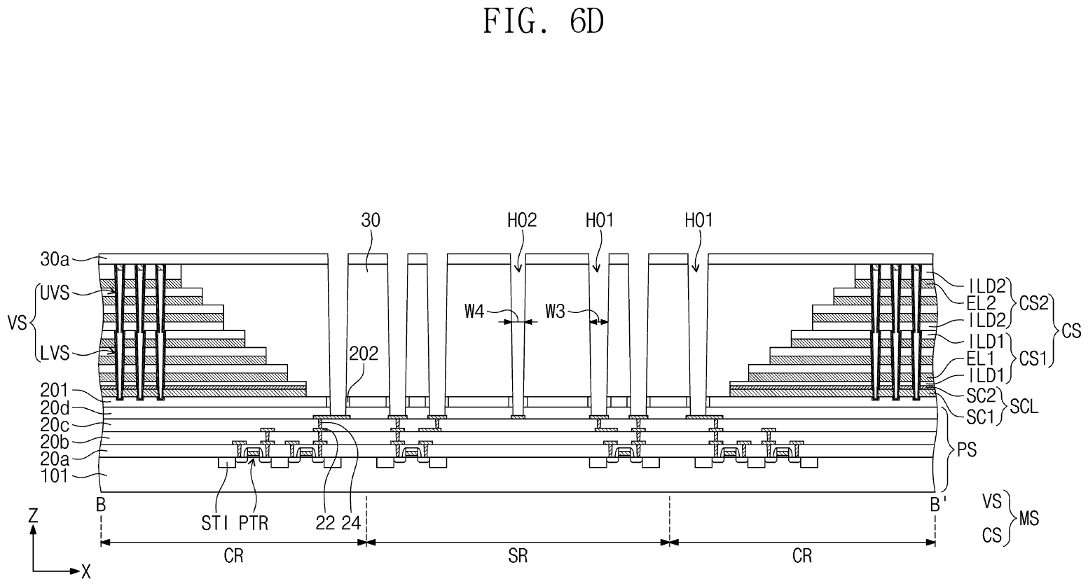

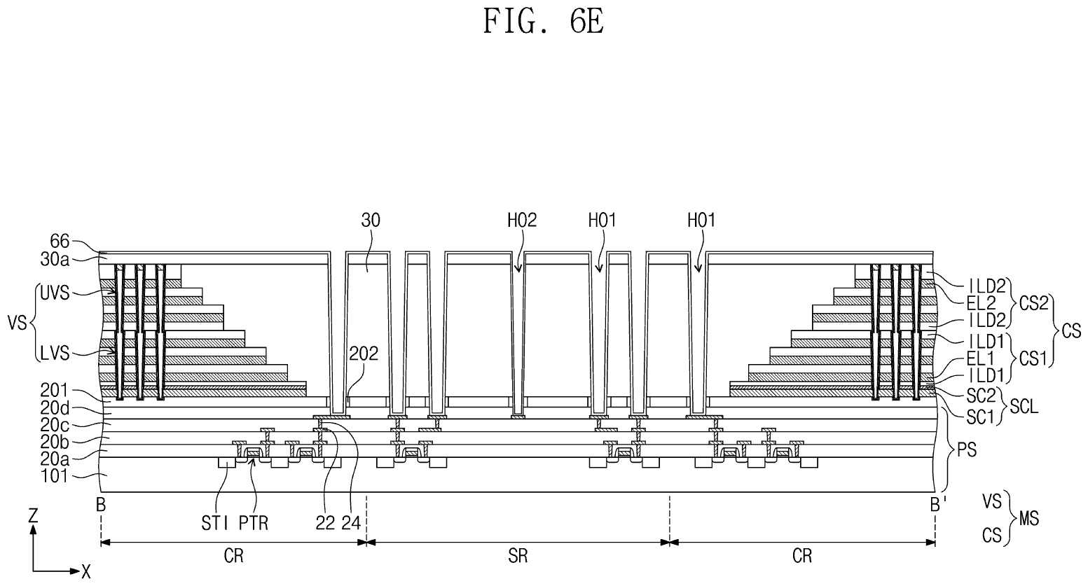

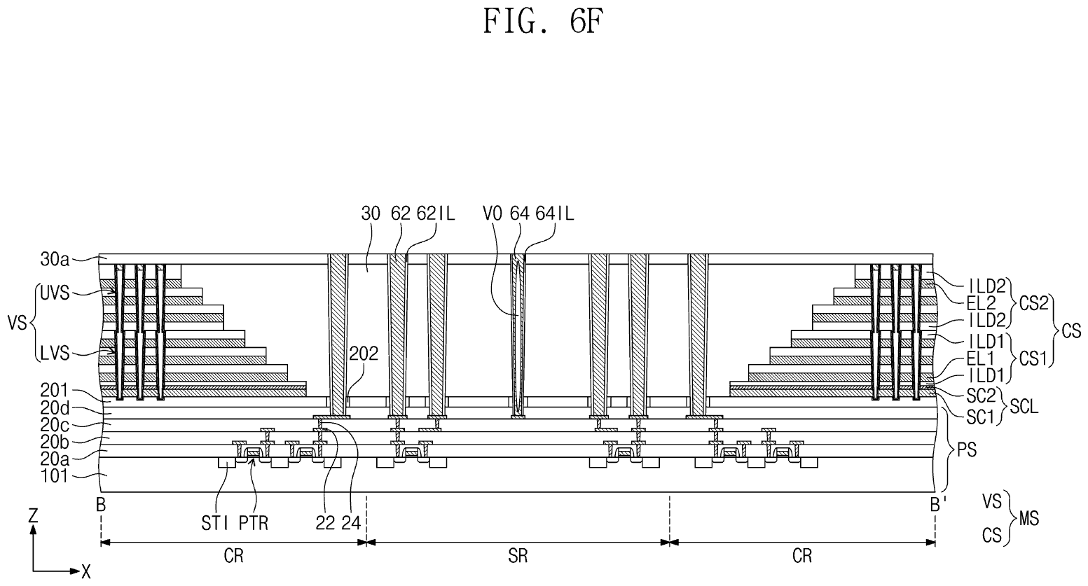

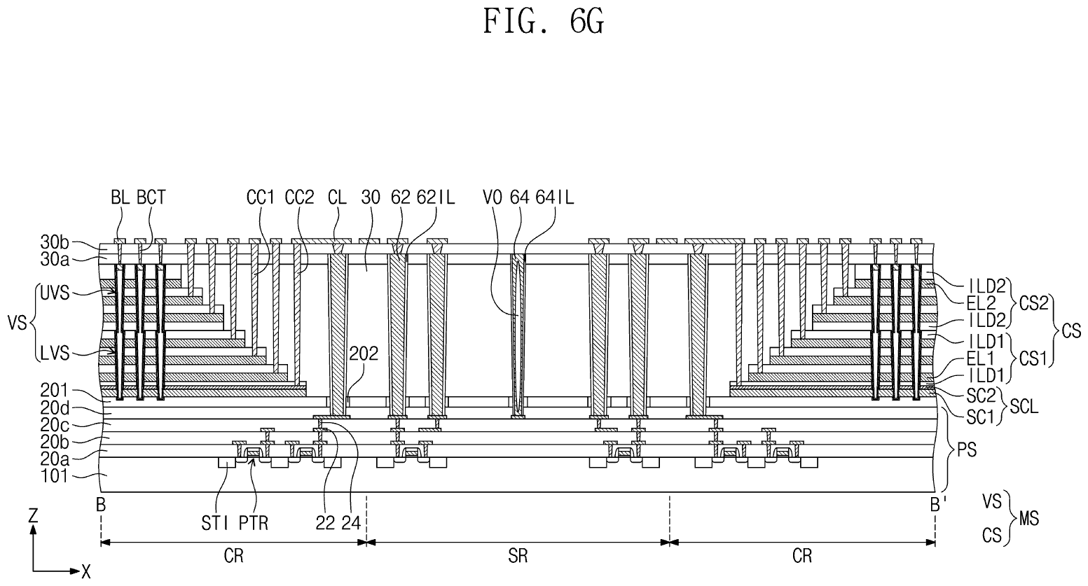

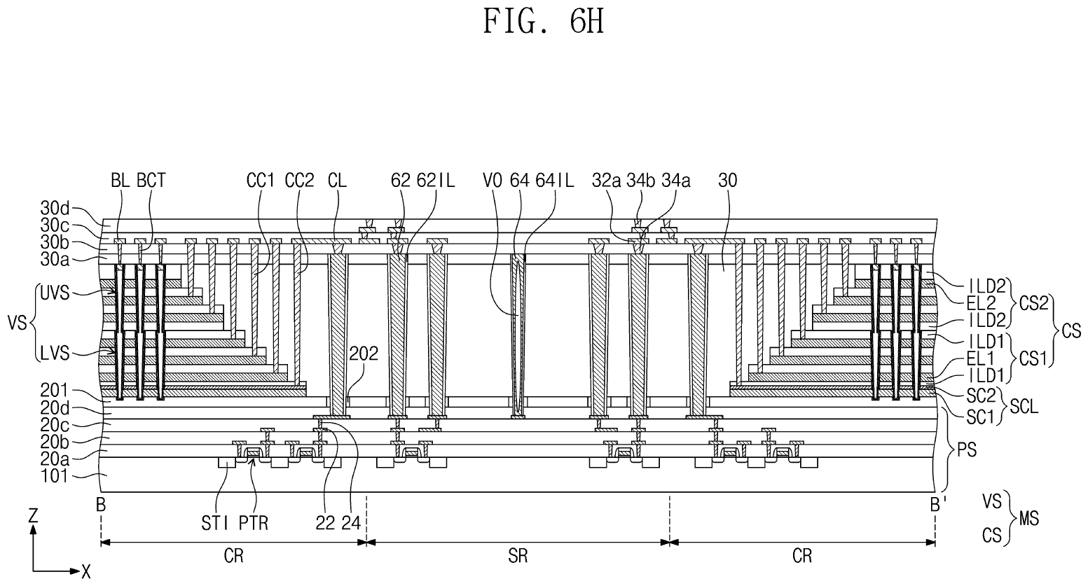

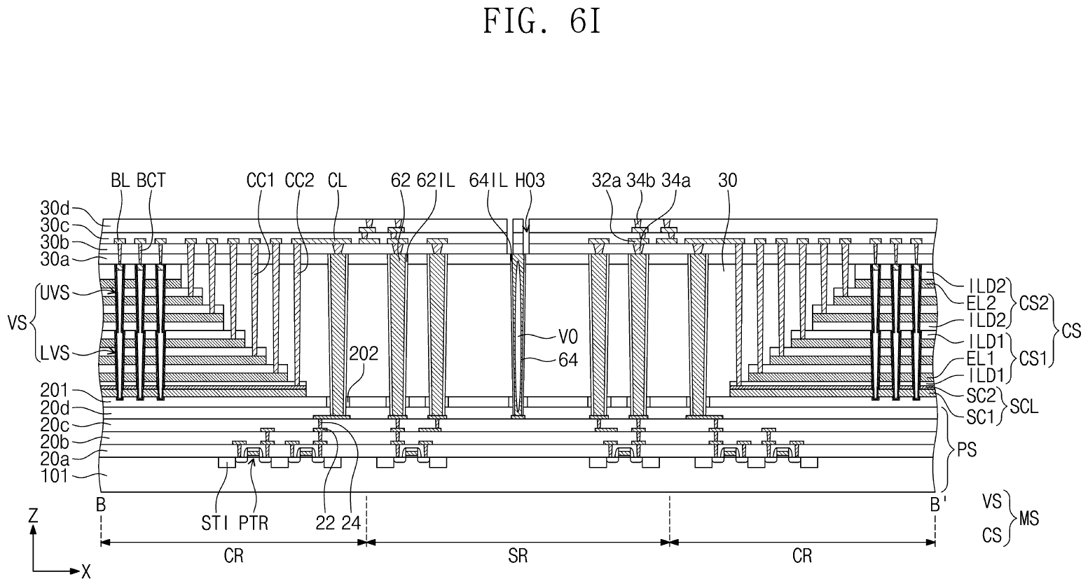

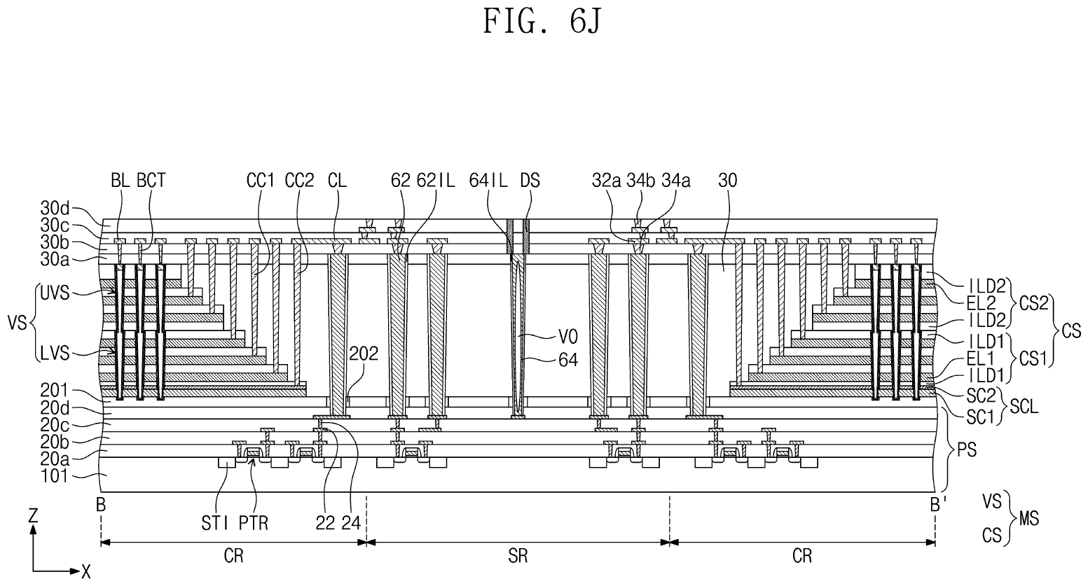

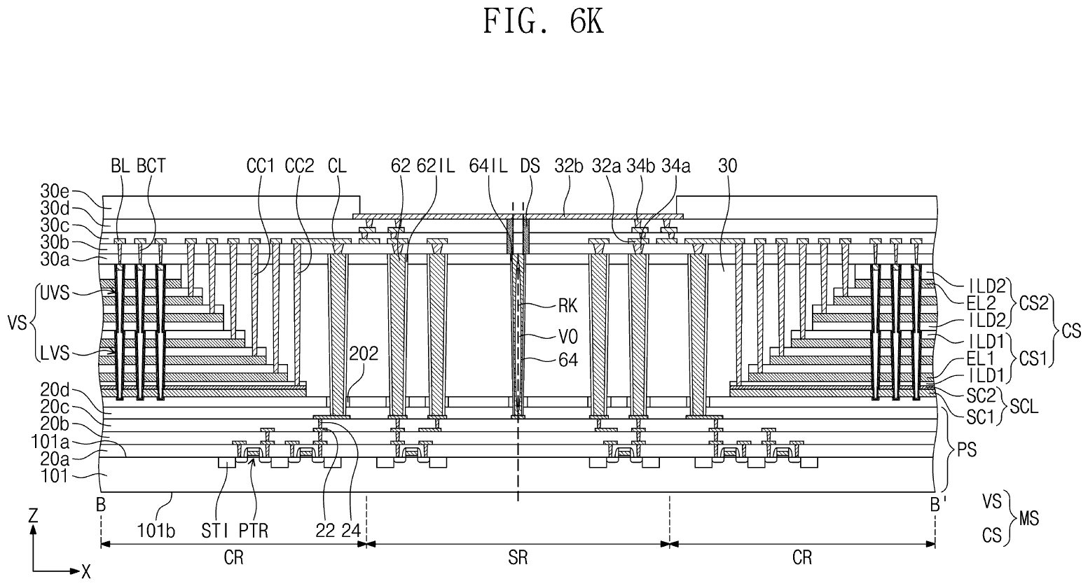

FIG. 5 is a plan view of a wafer. FIGS. 6A to 6K are cross-sectional views sequentially illustrating operations of manufacturing a semiconductor device having the cross-section of FIG. 2. FIGS. 6A to 6K are process cross-sectional views taken along line B-B′ of FIG. 5.

Referring to FIGS. 5 and 6A, a wafer WF is prepared. The wafer WF includes element regions CR and a scribe lane region SR disposed therebetween. The wafer WF may include configurations of the semiconductor device 1001 described with reference to FIG. 2.

The wafer WF may include a first substrate 101. Active regions may be defined by forming element isolation films STI on the first substrate 101. The element isolation film STI may be formed in a shallow trench isolation method. Peripheral transistors PTR are formed on the first substrate 101. A first peripheral insulating film 20a covering peripheral transistors PTR is formed on a front surface 101a of the first substrate 101. Contact holes are formed by etching the first peripheral insulating film 20a and are filled with a conductive material to form peripheral vias 24. A conductive film is stacked on the first peripheral insulating film 20a and is etched to form peripheral lines 22. First to fourth peripheral insulating films 20a to 20d, the peripheral lines 22, and the peripheral vias 24 are formed by repeating the above processes. Accordingly, a peripheral circuit structure PS may be formed.

Referring FIG. 6B, a second substrate 201 is formed on a fourth peripheral insulating film 20d. A plurality of trenches exposing the fourth peripheral insulating film 20d are formed by etching the second substrate 201 and are filled with an Insulating material to form a substrate insulating film 202.

Referring to FIG. 6C, a source structure SCL, a stack structure CS, and vertical channel structures VS are formed by performing a general process on the second substrate 201. The stack structure CS and the vertical channel structures VS may constitute an upper structure MS. ‘The upper structure’ may be referred to as ‘a memory cell structure’. An upper surface of the stack structure CS is exposed by forming a planarization insulating film 30 on the second substrate 201 and performing a polishing process. Thereafter, a first cell insulating film 30a is formed on the planarization insulating film 30 and the stack structure CS.

Referring to FIG. 6D, a plurality of first holes HO1 and a second holes HO2 exposing the peripheral lines 22 on the third peripheral insulating film 20c are formed by at least partially etching a first cell insulating film 30a, a planarization insulating film 30, the substrate insulating film 202, and third and fourth peripheral insulating films 20c and 20d. The first holes HO1 may be formed on the scribe lane region SR and the element region CR. The second hole HO2 may be formed on the scribe lane region SR. The first holes HO1 may be formed to have a third width W3. The second hole HO2 may be formed to have a fourth width W4. The fourth width W4 may be about 0.1 times to about 0.5 times of the third width W3.

Referring to FIG. 6E, a via insulating film 66 covering the first cell insulating film 30a and the first and second holes HO1 and HO2 is conformally formed.

Referring to FIG. 6F, an anisotropic etching process is performed to remove the via insulating film 66 on the first cell insulating film 30a and to expose an upper surface of the first cell insulating film 30a. In addition, the via insulating film 66 on the peripheral lines 22 is removed, and upper surfaces of the peripheral lines 22 are exposed. Accordingly, first and second via insulating films 62IL and 64IL are formed. In addition, penetration vias 62 and a dummy via 64 may be formed by filling the first and second holes HO1 and HO2 with a conductive film and performing a CMP process. However, an embodiment of the inventive concept is not limited thereto, and the second hole HO2 may not be filled with the conductive film, and a trench may be formed instead of the dummy via 64. Since a fourth width W4 of the second hole HO2 is smaller than a third width W3 of the first holes HO1, a void VO may be formed inside the dummy via 64 when the first and second holes HO1 and HO2 are filled with the conductive film.

Referring to FIG. 6G, a second cell insulating film 30b is formed on the first cell insulating film 30a, the penetration vias 62, and the dummy via 64. Thereafter, first and second cell contact holes are formed by etching the first and second cell insulating films 30a and 30b, the planarization insulating film 30, and the first and second interelectrode insulating films ILD1 and ILD2 and are filled with a conductive material to form first and second cell contact plugs CC1 and CC2.

Bit line contact holes are formed by etching the first and second cell insulating films 30a and 30b on the stack structure CS and are filled with a conductive material to form bit line contact BCT. First cell via holes are formed by etching the second cell insulating film 30b on the penetration vias 62 and are filled with a conductive material to form first cell vias 34a. A conductive film is stacked on the second cell insulating film 30b and is etched to form first cell lines CL and second cell lines 32a.

Referring to FIG. 6H, third and fourth cell insulating films 30c and 30d, second cell vias 34b, and the second cell lines 32a are formed by repeating a process described in FIG. 6G.

Referring to FIG. 6I, third holes HO3 exposing upper surfaces of the dummy via 64, the second via insulating film 64IL, and the first cell insulating film 30a are formed by etching the second to fourth cell insulating films 30b, 30c, and 30d on the scribe lane region SR.

Referring to FIG. 6J, the guide patterns DS are formed by filling the third holes HO3 with a conductive film and performing a CMP process. The guide patterns DS may be formed spaced apart from each other. The guide patterns DS may overlap the dummy pattern 64.

Referring to FIGS. 2, 3B, and 6K, a third cell lines 32b is formed by stacking and etching a conductive film on the fourth cell insulating film 30d of the scribe lane region SR. A fifth cell insulating film 30e is formed on the fourth cell insulating film 30d and the third cell lines 32b. Thereafter, a hole 30e_h exposing the third cell lines 32b is formed by etching the fifth cell insulating film 30e.

A grinding process of polishing a rear surface 101b of the first substrate 101 is performed. A physical force generated during the grinding process may be propagated from the inside of the first substrate 101 along side surfaces of the void VO and the guide patterns DS. Accordingly, a crack generated inside the first substrate 101 may be propagated along a crack line RK to cause other cracks in the first substrate 101, the first to third peripheral insulating films 20a, 20b, and 20c, the dummy via 64, and the third cell line 32b. Accordingly, the first substrate 101 may be separated to the element regions CR, and thus the wafer WF may be separated to the semiconductor devices 1001.

During this process, some of the peripheral lines 22 may be cut to form a line residual pattern 22T. Accordingly, a sidewall 22T_S of the line residual pattern 22T has great surface roughness as in FIG. 3. In addition, the dummy via 64 may be formed as a dummy pattern 64T. The dummy pattern 64T may have a sidewall 64_S not covered with the planarization insulating film 30 and exposed. Thereafter, a portion of the scribe lane region SR may be the edge region ER of the semiconductor device 1001.

The method for manufacturing a semiconductor device according to the inventive concept does not need to use laser beam or a blade to cut the wafer WF. Accordingly, a separate sawing process of cutting the wafer WF and separating the wafer WF to the semiconductor devices 1001 may not be necessary, thereby simplifying processes. In addition, the semiconductor device may be manufactured without a defect such as chipping or a crack capable of being generated by the sawing process. Accordingly, components of the element region of the semiconductor device may be prevented from being damaged. Accordingly, reliability of the semiconductor device may be improved and a yield thereof may be increased.

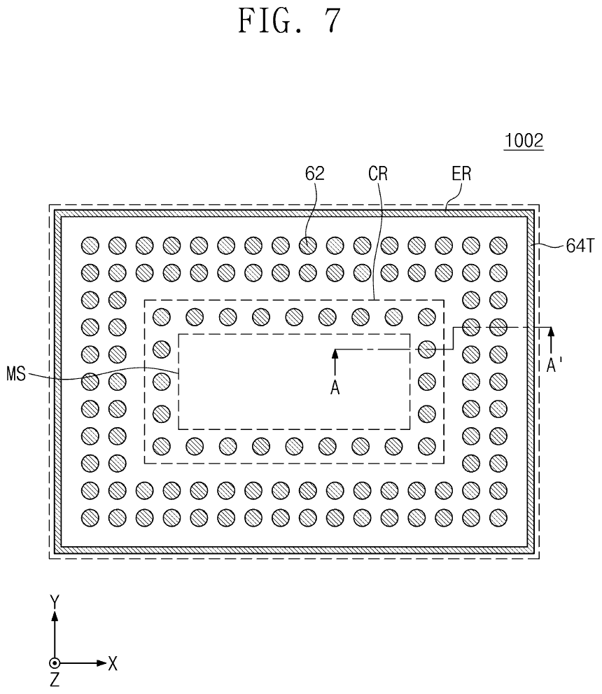

FIG. 7 is a plan view of a semiconductor device according to embodiments of the inventive concept. A cross-section taken along line A-A′ of FIG. 7 may correspond to FIG. 2.

Referring to FIG. 7, a semiconductor device 1002 according to the present embodiment may have a dummy pattern 64T having a closed rectangular ring shape. The dummy pattern 64T may be spaced apart from penetration vias 62 and may surround the penetration vias 62 on a plane. Other configurations may be the same as or similar to what is described with reference to FIGS. 1 to 6K.

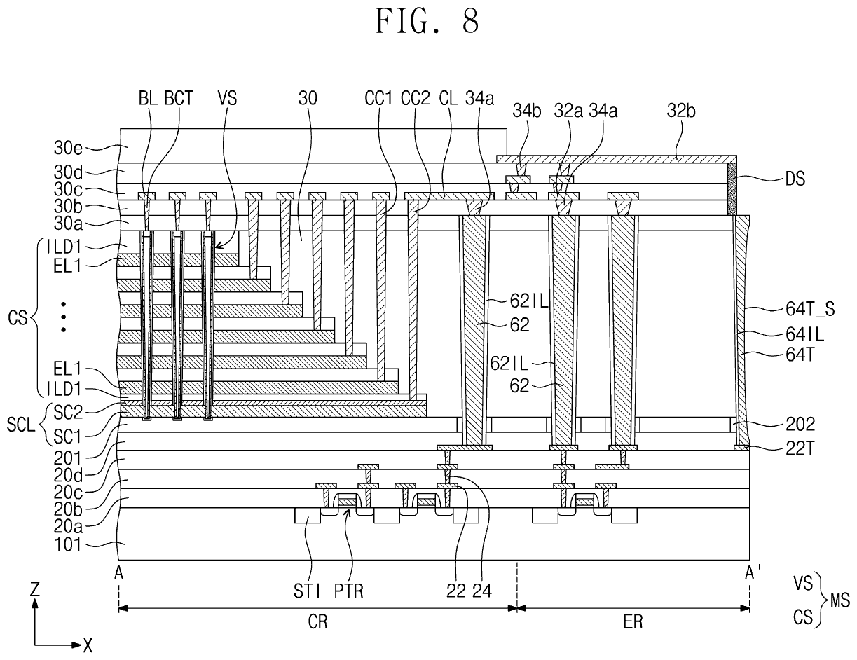

FIG. 8 is a cross-sectional view taken along line A-A′ of FIG. 1 according to embodiments of the inventive concept.

Referring to FIG. 8, in a semiconductor device according the present embodiment, a stack structure CS may include first electrode layers EL1 and first interelectrode insulating films ILD1 alternately stacked. Vertical channel structures VS may penetrate the stack structure CS and a source structure SCL to be adjacent to a second substrate 201. Each of the vertical channel structures VS may have a columnar form. Other configurations may be the same as or similar to what is described with reference to FIGS. 1 to 7.

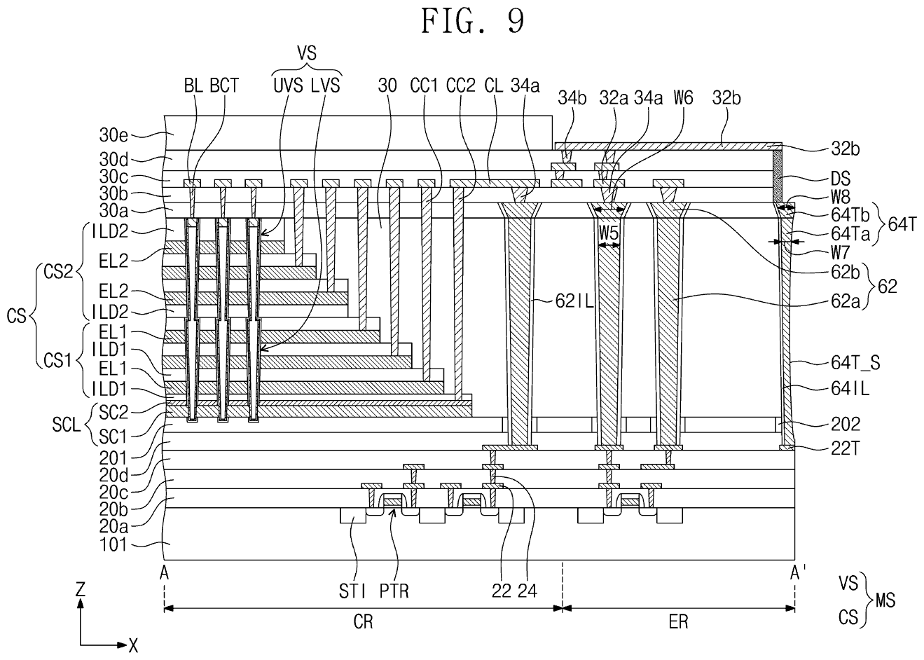

FIG. 9 is a cross-sectional view taken along line A-A′ of FIG. 1 according to embodiments of the inventive concept.

Referring to FIG. 9, according to the present embodiment, the penetration vias 62 may each include a first penetration via 62a and a second penetration via 62b. The first penetration vias 62a may penetrate a portion of a fourth peripheral insulating film 20d, a planarization insulating film 30, and a substrate insulating film 202 to be respectively in contact with peripheral lines 22. The second penetration via 62b may penetrate a first cell insulating film 30a to be disposed on the first penetration via 62a. A fifth width W5 of the first penetration via 62a may be smaller than a sixth width W6 of the second penetration via 62b.

A dummy pattern 64T may include a first dummy pattern 64Ta and a second dummy pattern 64Tb. The first dummy pattern 64Ta may penetrate a portion of a fourth peripheral insulating film 20d, a planarization insulating film 30, and a substrate insulating film 202 to be respectively in contact with peripheral lines 22. The second dummy pattern 64Tb may penetrate a first cell insulating film 30a to be disposed on the first dummy pattern 64Ta. A seventh width W7 of the first dummy pattern 64Ta may be smaller than an eighth width W8 of the second dummy pattern 64Tb. Other configurations may be the same as or similar to what is described with reference to FIGS. 1 to 7.

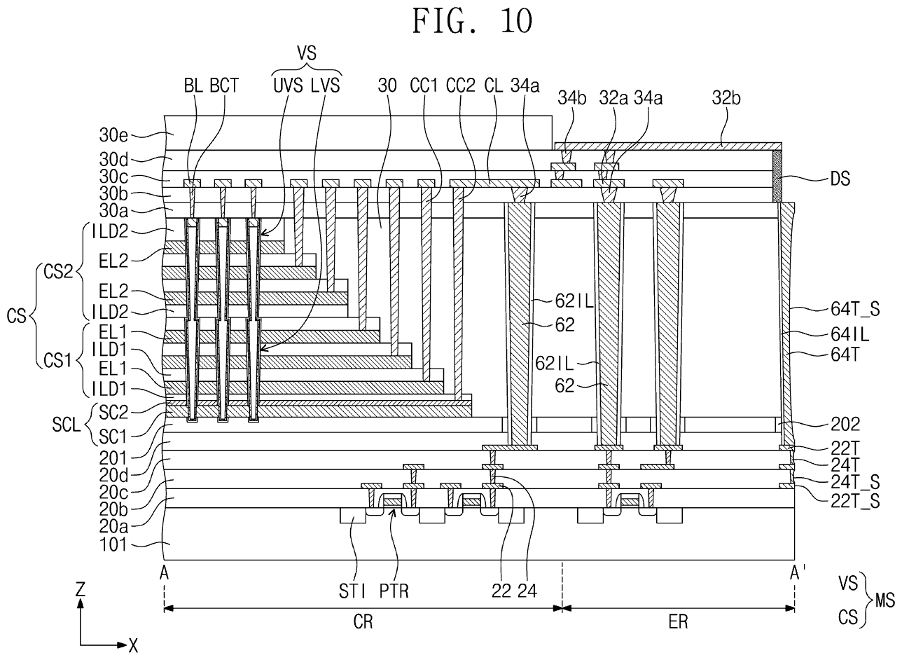

FIG. 10 is a cross-sectional view taken along line A-A′ of FIG. 1 according to embodiments of the inventive concept.

Referring to FIG. 10, in a semiconductor device according to the present embodiment, line residual patterns 22T may be further disposed on second and third peripheral insulating films 20b and 20c in an edge region ER. The line residual pattern 22T may overlap a dummy pattern 64T. Sidewalls 22T_S of the line residual patterns 22T may not be respectively covered with the second and third peripheral insulating films 20b and 20c and may be exposed.

Line residual patterns 24T may be further disposed on the second and third peripheral insulating films 20b and 20c in the edge region ER. The line residual patterns 24T may overlap the dummy pattern 64T. One sidewalls 24T_S of the line residual patterns 24T may not be respectively covered with the second and third peripheral insulating films 20b and 20c and may be exposed. A width of each of the via residual patterns 24T may be smaller than a width of each of peripheral vias 24. Other configurations may be the same as or similar to what is described with reference to FIGS. 1 to 7.

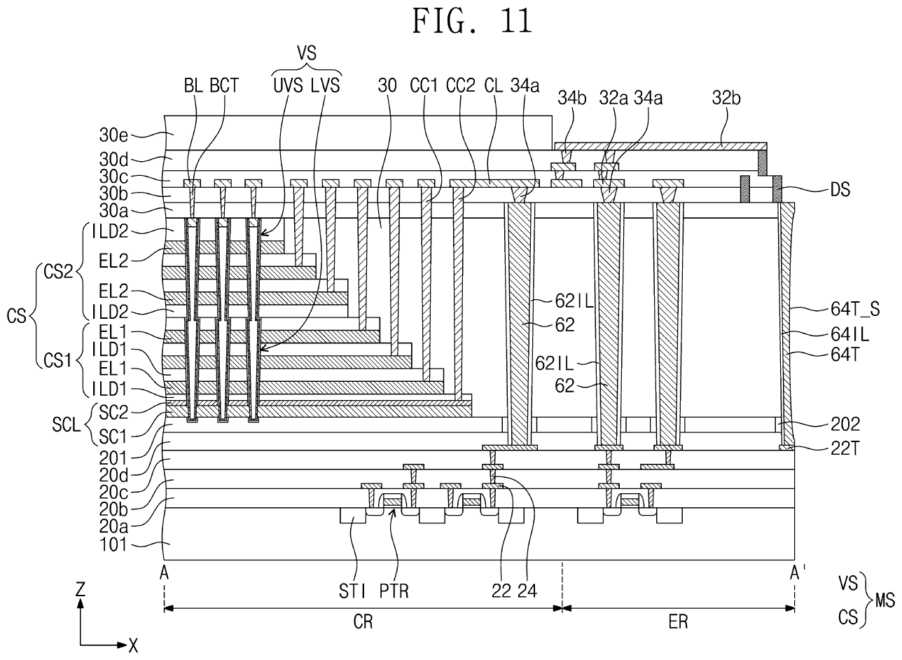

FIG. 11 is a cross-sectional view taken along line A-A′ of FIG. 1 according to embodiments of the inventive concept.

Referring to FIG. 11, in a semiconductor device according to the present embodiment, a guide pattern DS may be provided in plurality. The guide patterns DS may be spaced apart from each other in the first direction X. The guide patterns DS may be spaced apart from each other in the third direction Z. One of the guide patterns DS may at least partially penetrate second and third cell insulating films 30b and 30c. Another one of the guide patterns DS may at least partially penetrate third and fourth cell insulating films 30c and 30d. Other configurations may be the same as or similar to what is described with reference to FIGS. 1 to 7.

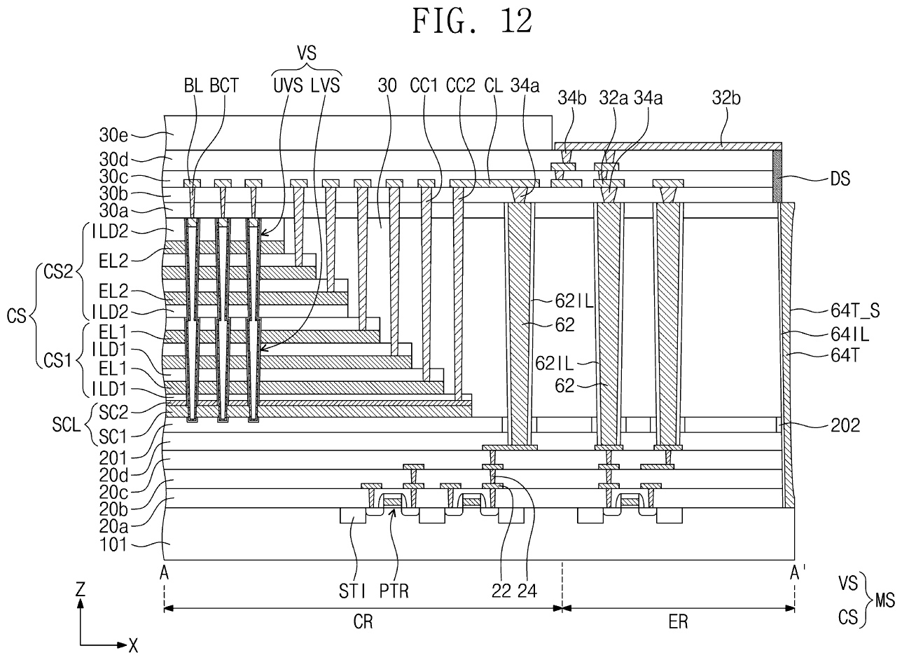

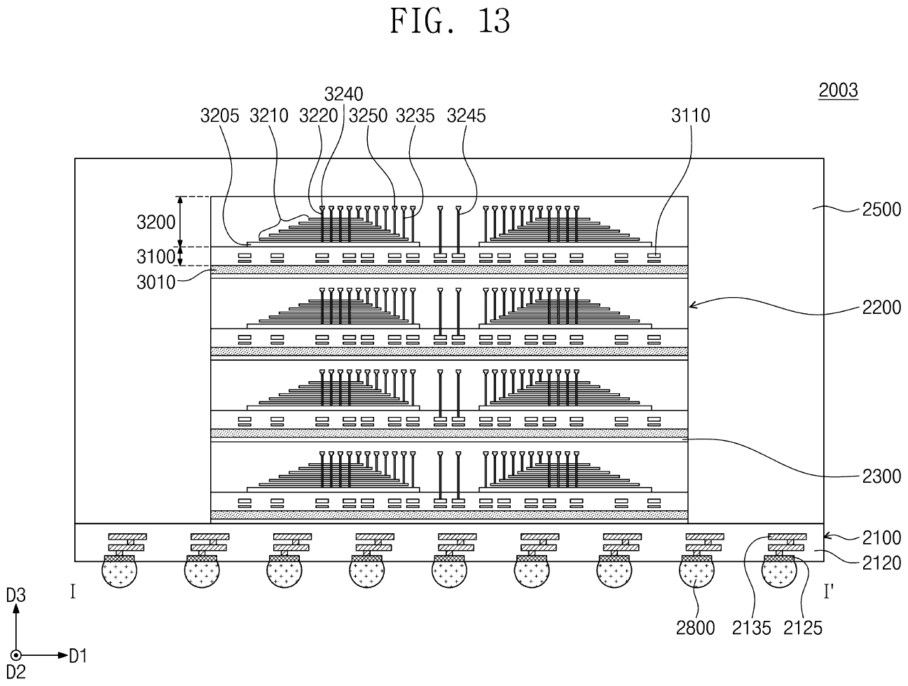

FIG. 12 is a cross-sectional view taken along line A-A′ of FIG. 1 according to embodiments of the inventive concept.

Referring to FIG. 12, in a semiconductor device according to the present embodiment, a dummy pattern 64T may extend to penetrate first to fourth peripheral insulating films 20a to 20d. The dummy pattern 64T may be in contact with a first substrate 101. Other configurations may be the same as or similar to what is described with reference to FIGS. 1 to 7.

FIG. 13 is a cross-sectional view of a semiconductor package according to embodiments of the inventive concept.

Referring to FIG. 13, a semiconductor package 2003 according to the present embodiment may include a package substrate 2100. The package substrate 2100 may be a printed circuit board. The package substrate 2100 may include a package substrate body 2120, package upper pads (not shown) disposed on an upper surface of the package substrate body 2120, lower pads 2125 disposed on a lower surface of the package substrate body 2120 or exposed through the lower surface of the package substrate body 2120, and internal lines 2135 disposed in the package substrate body 2120.

Semiconductor chips 2200 may each include a semiconductor substrate 3010, and a first structure 3100 and a second structure 3200 sequentially stacked on the semiconductor substrate 3010. The first structure 3100 may include a peripheral circuit region including peripheral lines 3110. The second structure 3200 may include a source structure 3205, a stack structure 3210 on the source structure 3205, vertical structures 3220 and isolation structures 3230 penetrating the stack structure 3210, bit lines 3240 electrically connected to the vertical structures 3220, and cell contact plugs 3235 electrically connected to word lines of the stack structure 3210.

The semiconductor chips 2200 may each include a penetration line 3245 electrically connected to the peripheral lines 3110 of the first structure 3100 and extending into the second structure 3200. The penetration line 3245 may be disposed outside the stack structure 3210 and may be further disposed to penetrate the stack structure 3210. Each of the semiconductor chips 2200 may further include an input-output pad (not shown) electrically connected to the peripheral lines 3110 of the first structure 3100.

For example, the first structure 3100 may correspond to the peripheral circuit structure PS of FIG. 2, and the second structure 3200 may correspond to the upper structure MS of FIG. 2. The semiconductor chips 2200 may respectively correspond to the semiconductor devices 1001 and 1002 described with reference to FIGS. 1 to 12.

In a semiconductor device according to the inventive concept, since a guide pattern is disposed in the outermost side of an edge region and surrounds an element region in a plan view, moisture or the like may be prevented from infiltrating from the outside into the inside of cell Insulating films. Accordingly, reliability of the semiconductor device may be improved.

According to the inventive concept, since a blade, laser, or the like is not used to cut a wafer, the semiconductor device may be manufactured without a defect such as chipping or a crack. A separate sawing process of cutting the wafer may not be necessary, thereby simplifying processes. Accordingly, reliability of the semiconductor device may be improved and a yield thereof may be increased.

Although the embodiments of the present invention have been described, it is understood that the present invention should not be limited to these embodiments but various changes and modifications can be made by one ordinary skilled in the art within the spirit and scope of the present invention as hereinafter claimed.

1. A semiconductor device comprising:
a first substrate including an element region and an edge region;
peripheral insulating films on the first substrate;
a memory cell structure on the peripheral insulating films in the element region;
a planarization insulating film at least partially covering the peripheral insulating films and an end portion of the memory cell structure;
cell insulating films on the memory cell structure and the planarization insulating film;
a penetration via penetrating at least a portion of the peripheral insulating films and the planarization insulating film in the element region;
a cell via on the penetration via;
a dummy pattern penetrating at least a portion of the peripheral insulating films and the planarization insulating film in the edge region; and
a guide pattern penetrating the cell insulating films to contact the dummy pattern,
wherein the guide pattern has a first height from an upper end of the dummy pattern, and
wherein the cell via has a second height, from an upper end of the penetration via, smaller than the first height.

2. The semiconductor device of claim 1, further comprising peripheral transistors on the first substrate under the peripheral insulating films,
wherein the memory cell structure includes:
electrode layers and interelectrode insulating films alternately repeatedly stacked; and
vertical semiconductor patterns penetrating the electrode layers and the interelectrode insulating films.

3. The semiconductor device of claim 1, wherein the penetration via has the same height as the dummy pattern, and
wherein a width of the penetration via is greater than a width of the dummy pattern.

4. The semiconductor device of claim 1, wherein the penetration via and the dummy pattern are each provided in plurality,
wherein the penetration vias at least partially surround the memory cell structure in a plan view, and
wherein the dummy patterns at least partially surround the penetration vias in a plan view.

5. The semiconductor device of claim 1, wherein a sidewall of the dummy pattern is flush with a sidewall of the first substrate.

6. The semiconductor device of claim 1, further comprising a first via insulating film between the penetration via and the planarization insulating film, and a second via insulating film between the dummy pattern and the planarization insulating film.

7. The semiconductor device of claim 1, wherein the dummy pattern and the penetration via comprise a same material.

8. The semiconductor device of claim 1, wherein the dummy pattern comprises:
a first part;
a second part; and
a third part located on the first part, the first part being between the second part and the third part, and
wherein the first to third parts respectively comprise first to third sidewalls that are free of the planarization insulating film and the peripheral insulating films, and
wherein the second and third sidewalls have greater surface roughness than the first sidewall.

9. The semiconductor device of claim 1, wherein a sidewall of the guide pattern and a sidewall of the dummy pattern are arranged to have a step relationship with each other.

10. The semiconductor device of claim 1, wherein one sidewall of the guide pattern is free of the cell insulating films.

11. The semiconductor device of claim 1, wherein the dummy pattern comprises:
a first dummy pattern penetrating the planarization insulating film; and
a second dummy pattern on the first dummy pattern penetrating the lowest cell insulating film, and
a width of the first dummy pattern is smaller than a width of the second dummy pattern.

12. A semiconductor device comprising:
a first substrate including an element region and an edge region;
peripheral transistors on the first substrate;
peripheral insulating films on the first substrate and the peripheral transistors;
a stack structure on the peripheral insulating films in the element region, and including electrode layers and interelectrode insulating films alternately repeatedly stacked;
vertical channel structures at least partially penetrating the stack structure;
a planarization insulating film at least partially covering the peripheral insulating films and an end portion of the stack structure;
cell insulating films on the stack structure and the planarization insulating film;
a penetration via penetrating at least a portion of the peripheral insulating films and the planarization insulating film in the element region;
a cell via on the penetration via;
a dummy pattern penetrating at least a portion of the peripheral insulating films and the planarization insulating film in the edge region; and
a guide pattern penetrating the cell insulating films to contact the dummy pattern,
wherein the guide pattern has a first sidewall that is free of the cell insulating films,
wherein the dummy pattern has a second sidewall that is free of the peripheral insulating films and the planarization insulating film, and
wherein the first sidewall and the second sidewall are arranged to have a step relationship with each other.

13. The semiconductor device of claim 12, wherein the penetration via and the dummy pattern are each provided in plurality,
wherein the penetration vias at least partially surround the stack structure in a plan view, and
wherein the dummy patterns at least partially surround the penetration vias in a plan view.

14. The semiconductor device of claim 12, wherein the penetration via has a same height as the dummy pattern, and
a width of the penetration via is greater than a width of the dummy pattern.

15. The semiconductor device of claim 12, wherein the dummy pattern is in contact with the first substrate.

16. The semiconductor device of claim 12, wherein the cell insulating films comprise first, second, and third cell insulating films sequentially stacked,
wherein the guide pattern is provided in plurality,
wherein one of the guide patterns at least partially penetrates the first and second cell insulating films,
wherein another one of the guide patterns at least partially penetrates the second and third cell insulating films.

17. The semiconductor device of claim 12, further comprising:
peripheral vias in the peripheral insulating films, the peripheral vias connected to the peripheral transistors; and
via residual patterns on the edge region and in the peripheral insulating films,
wherein the via residual patterns overlap the dummy pattern, and
at least one sidewall of the via residual patterns is free of the peripheral insulating films.

18. The semiconductor device of claim 17, wherein a width of any of the via residual patterns is smaller than a width of any of the peripheral vias.

19. A semiconductor device comprising:
a first substrate including an element region and an edge region;
peripheral insulating films on the first substrate;
a memory cell structure on the peripheral insulating films in the element region;
a planarization insulating film at least partially covering the peripheral insulating films and an end portion of the memory cell structure;
cell insulating films on the memory cell structure and the planarization insulating film;
a dummy pattern penetrating at least a portion of the peripheral insulating films and the planarization insulating film in the edge region; and
a guide pattern penetrating the cell insulating films to contact the dummy pattern,
wherein the guide pattern has a first sidewall free of the cell insulating films,
wherein the dummy pattern has a second sidewall free of the peripheral insulating films and the planarization insulating film, and
wherein the first sidewall has lower surface roughness than the second sidewall.

20. The semiconductor device of claim 19, further comprising:
a penetration via penetrating at least a portion of the peripheral insulating films and the planarization insulating film in the element region; and
a line residual pattern and peripheral lines in the peripheral insulating films and spaced apart from each other,
wherein one of the peripheral lines is connected to the penetration via,
wherein the line residual pattern has a third sidewall that is free of the peripheral insulating films, and
wherein the third sidewall has greater surface roughness than the first sidewall.

21-24. (canceled)
